(19) United States
(12) Patent Application Publication
(10) Pub. No.: US 2019/0305165 A1
(43) Pub. Date: Oct. 3, 2019

(54) PHOTOVOLTAIC MODULE

(71) Applicant: BASF COATINGS GMBH, Muenster (DE)

(72) Inventors: Patrice Bujard, Basel (CH); Vjosa Statovci, Muenster (DE); Jan-Bernd Kues, Muenster (DE); Adrian von Muehlenen, Muenster (DE); Tobias Hintermann, Therwil (CH); Jan Gebers, Basel (CH); Sven Olle Krabbenborg, Muenster (DE)

(21) Appl. No.: 16/302,737

(22) PCT Filed: May 9, 2017
(86) PCT No.: PCT/EP2017/061062

§ 371 Date: Nov. 19, 2018

(30) Foreign Application Priority Data
May 19, 2016 (EP) 16170280.8
Apr. 6, 2017 (EP) 17165302.5

(51) Int. Cl. H01L 31/056; H01L 31/0236; H01L 31/049; H01L 31/18

(52) U.S. Cl. CPC H01L 31/056; H01L 31/18; H01L 31/049; H01L 31/02366

(57) ABSTRACT

Described herein is a structured reflector for a photovoltaic module, where the structured reflector provides improved light conversion and efficiency, and a photovoltaic module comprising the reflector. In a photovoltaic module, a reflector sheet is arranged below photovoltaic cells, with a microstructured surface of the reflector sheet facing towards the cells. The microstructured surface comprises three-dimensional reflectors in the form of cones, whose apexes direct towards an upper surface of the photovoltaic module and whose aperture ranges from 100° to 140°.

Present invention relates to a structured reflector for a photovoltaic module, which provides improved light conversion and efficiency, and to a photovoltaic module comprising the reflector.

Typical photovoltaic modules, or solar modules, comprise an array of photovoltaic (PV) cells, generally formed from 2 or more “strings” of PV cells, with each string consisting of a plurality of PV cells arranged in a row and electrically connected in series using tinned flat copper wires, also known as electrical connectors, tabbing ribbons or bus wires. These electrical connectors are typically adhered to the PV cells by a soldering process.

The PV cells are typically arranged on transparent polymer layer or encapsulated in such a layer, such as generally described in U.S. Pat. No. 8,581,094 (Patel et al). In some embodiments, the PV module includes encapsulant on both sides of the PV cell. Two panels of glass or other suitable polymeric material usually are positioned adjacent and bonded to the front side and backside of the encapsulant. The two panels are transparent to solar radiation and are referred to as front side layer or front cover member, and backside layer or back sheet, respectively. The front side layer and the back sheet may be made of the same or a different material. The encapsulant is a light-transparent polymer arranged around the PV cells (in optical contact with the cell, such that it encapsulates the PV cells) and is also bonded to the front side layer and back sheet so as to physically seal off the cells. This laminated construction provides mechanical support for the cells and also protects them against damage due to environmental factors such as wind, snow and ice.

Each PV cell is fairly small, and cells thus cover only a fraction of the total surface area of the module. In consequence, there are portions of light, which pass through the distances between cells, or even pass through cells without being absorbed (in the following referred to as “passed light”) and strike the back sheet. A variety of techniques have been developed to direct more sunlight onto the solar cell and thus increase the efficiency of the module. In one technique described in U.S. Pat. No. 4,235,643 (Amick), an optical medium having a plurality of light-reflective facets is disposed around and between circular cells. The light-reflective facets are angularly disposed so as to define a plurality of grooves with the angle at the vertex formed by two mutually converging facets being between 110° to 130°, preferably about 120°. The result of these facets is that light impinging on the facets will be reflected back into the transparent front cover member at an angle greater than the critical angle, and is then reflected again internally from the front surface of the cover member so as to impinge on the solar cells. In U.S. Pat. No. 5,994,641 (Kardauskas), a flexible reflector means is used as the optical medium, having a plurality of grooves. The flexible reflector means is an optically reflective sheet material with a coating of reflective metal such as silver or aluminum. The surface of the reflecting sheet is in direct contact with the light-transparent polymer material encapsulant. Both techniques require exact alignment of the reflector means with the cells, and do not contribute to usage of light passing the cell without being absorbed.

EP-A-2357673 proposes a structured reflector sheet arranged under the cells throughout the module, thus providing reflection not only of light passing through gaps between cells, but also of “unused” light passing through the cells. Reflecting structures have concave side faces in order to avoid reflected light to strike opposite structures.

It has now been found that a certain microstructuring of the back sheet's surface, which faces the cells, or introduction of a reflective sheet containing certain microstructures “behind” the cells, may greatly improve the efficiency of such cells by reflecting a larger portion of passed light towards the cells and facilitate the production of the modules since alignment of cells and back sheet is not necessary. Besides redirecting light falling through the distances between cells (A, typical gap between cells), it also may reflect light passing the PV cell without getting absorbed, which happens especially in case of long wavelenths such as IR radiation, where the probability of interaction with the cell's PV material is reduced. The present reflector sheet is in direct optical contact with a transparent polymer layer (see details below), and serves by its structuring to direct such “passed light” in all directions within that layer. A repeated passage through the cell after reflection by the present structured reflector, and, in case of renewed passage, potentially again after total reflection at the surface of the mudule's front plate, enhances the module's overall efficiency. The present reflector sheet further simplifies manufacturing, since no preferred orientation of structures is required, neither with respect to cells within the module, nor with respect to incoming light, and few manufacturing steps are required. For example, a minimum of materials and layers is required for manufacturing of the present PV module, though such materials and/or layers, if introduced, may bring about additional advantages.

The present invention provides a way for enhancing the output of solar modules by enabling more light to hit the solar cells.

The invention thus primarily pertains to a photovoltaic module comprising an upper surface and a lower surface, where an array of photovoltaic cells is arranged on a polymer layer, characterized in that a reflecting layer is arranged parallel to the cells and below said polymer layer, whose surface facing the module's upper surface comprises three-dimensional reflectors in the form of cones whose apexes direct towards the upper surface and whose aperture (angle at top of cone a, see FIG. 3, or shown as angle β in FIG. 9b) is from the range 100 to 140°, preferably from the range 110 to 130°, especially about 120° (i.e. 120°+−2°; “flat cones”). The reflecting layer usually arranged below the cells to at least cover the distances A between cells (present FIGS. 4-6).

Thus, the invention includes a solar energy system comprising
a plurality of solar cells where some cells are spaced (distance A) from each other by areas without solar cells,
the light-reflecting film defined above overlapping with said areas without solar cells,
   the light-transparent polymer encapsulating the light-reflecting film and the solar cells.

The invention thus further pertains to a method for preparing a photovoltaic module, which method comprises incorporation of a reflector sheet (5) into the module, which reflector sheet comprises three-dimensional reflectors in the form of cones whose aperture is from the range 100 to 140°, preferably in the space between cells (3) and back sheet (7) with the apexes of the cones facing the cells; the present reflector sheet (5) may replace the back sheet (7) or be a part of it. Further details of the method of the invention are as explained for the photovoltaic module of the invention.

### DETAILED DESCRIPTION

Described herein are the structured reflector sheets, the solar modules comprising these sheets, the polymeric encapsulants as well as the methods of manufacturing the structured reflector sheets and the solar modules.

One aim of the invention is the implementation of light guiding structures to harvest light hitting the inactive areas of the module and thereby increasing PV module efficiency. Commonly used white diffusely reflecting backsheets typically only guide half of the light onto the cells. Metallic structures can guide nearly 75% of the light onto the cell increasing module efficiencies under standard testing conditions (STC).

Hereafter, the term “film” is synonymous with a sheet and like structures.

The expression “structured reflector sheet” or “microstructured reflector sheet” is synonymous with reflector sheet, structured reflector film, light reflecting film, structured back sheet.

The term “reflecting layer” or “structured reflecting film” denotes the surface or material layer (e.g. metal layer) on the structured reflector sheet causing light reflection.

The term “upper” and “front” denotes the side directed towards the incident light and the term “low”, “lower”, “below” and “back” denotes the opposite side.

The term “back sheet” denotes the lower cover of the photovoltaic module.

The term “base layer” denotes the lower part of the structured reflector sheet carrying the reflecting layer.

The terms “solar cell” or “PV cell” denotes any photovoltaic cell, such as monocrystalline cells, multicrystalline cells, ribbon silicon cells, thin film cells, etc., in the form of a monofacial or bifacial cell.

The term “transparent” denotes a transmission of visual light essentially without scattering, typically effecting solar light transmisssion of more than 90% with scattering less than 5%. A transparent material thus generally denotes a material of optical quality.

The term “Angstrom” denotes a length of 10⁻¹⁰ meter.

The term “solar module” is synonymous with a photovoltaic module or PV module.

The assembly containing the present optical element, e.g. the solar energy system or solar module, generally is mounted in a way to distinguish between front side and back side; the term “inner surface” thus defines a surface of a layer or film or material directed away from the front or back side, whichever is nearer.

Whereever mentioned, the refractive index of a material is as determined for a radiation of 589 nm (sodium D line), if not indicated otherwise.

The solar module according to the invention comprises a plurality of electrically interconnected solar cells having a front side receiving the incident and reflected light. The solar cells are arranged in a pattern where at least two cells are spaced from each other by areas with no solar cells and the light-reflecting films overlap with the areas free of solar cells.

The principle of the invention is independent of the current conventional column/row arrangement of solar cells in solar modules. According to one embodiment, the solar cells are arranged in rows and columns, where at least one of the rows or columns are being spaced from each other.

The reflector sheet is in direct optical contact with the encapsulant (i.e. the polymer layer or lowest polymer layer below the cells). Its surface reflects the light in the region where the PV cells are sensible, e.g. by the refractive index of the sheet with its three-dimensional reflectors, or a reflecting layer on such surface, differing from the refractive index of the encapsulant by at least 0.3, preferably by 0.5 or more, or by a metallic (mirror) surface. The metallic surface may result from metallization, e.g. by vapor deposition of a suitable metal film like aluminum, silver, copper, tin, nickel, or combinations of such metals. Alternatively, the metallic surface may result from the original metal sheet, such as used for the production of the PV module's back sheet. To promote a reflection for the wavelengths between 250 to 1500 nm, silver, aluminum or combinations thereof are preferred. The metallic coating is very thin, on the order of 300-1000 Angstroms thick, more preferably 300-500 Angstroms. The reflection may alternatively be provided by other materials such as reflective polymers.

The reflector sheet is arranged above the back sheet or is integrated in the back sheet forming its upper surface. The back sheet may be transparent or opaque, e.g. a glass sheet, coated glass sheet, polymer sheet (from polymers e.g. as noted below for the encapsulant, or semi-transparent or non-transparent polymers such as polyolefins, filled polymers, polymer laminates containing further materials such as metal films), metal sheet, coated metal sheet. Typically, the microstructured reflecting films may be located anywhere between the solar cells and the back sheet of the solar module as long as they overlap with the areas free of solar cells.

The three-dimensional reflectors may be prepared, for example, in a casting or embossing step on a polymer sheet or metal sheet, or on a polymer film attached or attachable to a glass sheet. Also possible is the forming (e.g. in an embossing step) of a polymer curable by radiation or heat, whose curing is effected during or shortly after the embossing step. The metallic surface is then applied by metallization as described above.

The cones may have a circular or elliptical or polygonal base and may be of same or of varying/alternating size. In case of a polygonal base, the pyramidal cones (or, in case that the structure comprises 2 or more types of cones, the largest cones) preferably have at least 6 lateral surfaces (i.e. the base preferably is a hexagon, heptagon, octagon etc., and preferably not a pentagon, square or triangle). In case of an elliptical base, the minor radius typically is at least 30%, preferably at least 50%, of the major radius; preferably, the cones are mainly circular (i.e. have a mainly circular base, where the term “mainly” denotes deviation of minor from major radius by up to 10%). In another preferred embodiment, at least a fraction of the cones have a hexagonal basis. In a preferred embodiment, the cones protrude from a flat surface such that there is no “flat” area left, i.e. the cones' bases may be overlapping where structures are chosen whose bases do not completely fill the surface, or the cones' bases are directly adjacent to each other as preferably realized for cones of hexagonal basis (also denoted as hexagonal pyramids), such that the reflector sheet's surface is made up of the cones' lateral surfaces. An especially important structure is made up of cones, whose base is a triangle, and of hexagonal cones, as schematically shown in FIG. 2c; these structures combine high efficiency with easy manufacturing of the mold or the reflector itself by micromachining. The height of the cones is typically from the range 10 to 100 micrometer; typical dimensions of circular cones are given in the following table 1 (“angle at top of cone denotes the aperture; “mu” stands for micrometer). The roughness of the cones' lateral surfaces is not critical since no exact angle of reflection is required in order to realize the improvement by the invention.

TABLE 1
Typical cone dimensions (mu stands for micrometer)

| apex angle (aperture) | height (mu) | cone radius (mu) |
|---|---|---|
| 100° | 25 | 30 |
| 110° | 25 | 36 |
| 120° | 25 | 43 |
| 130° | 25 | 54 |
| 140° | 25 | 69 |

Any degree of roughness on the surface of the cones may lead to the angle of the reflected light varying over the light-reflecting films; this can lead to a non-negligible amount of loss of incident radiation. The surfaces of the grooves thus preferably are sufficiently plane in order for the light rays not to be reflected with scattering. The light-reflecting films thus preferably are adapted to provide substantially specular (not diffuse) reflection of the incident light beam, with roughness of the surfaces sufficiently small so that only a small amount of the incident light encounters areas where the vertex angle of the grooves deviates by more than a few degrees from the desired angle. The tolerance for variation in angle depends on the desired angle; for a desired angle of 120°, for example, the reflection angle preferably should not deviate by more than of the order 10° from this optimum, otherwise a non-negligible amount of the incident radiation might be lost.

A typical example for a reflecting back sheet structured in accordance with the invention is shown in FIG. 1 (cross section with reversed sides, cones' tops with aperture (a) of 120° facing towards the PV cells, cones height (h) 25 micrometer, diameter of base 87 micrometer; the structured surface is metallized by a thin reflecting layer (R) of vapor deposited aluminum, thickness e.g. 0.1 to 1 micrometer). A full cross section of a corresponding PV module is shown in FIG. 4 with transparent front plate (1), e.g. glass or a polymer cover, PV cells (3) separated by a distance (A) and fully encapsulated in a polymer such as EVA including upper layer (2) and lower layer (4), and structured reflector of the invention (5) in close proximity or attached to the upper surface of the back sheet (7).

For practical and manufacturing reasons, the cones' apexes often are slightly rounded or flattened (e.g forming a relatively flat or just slightly curved surface, or even an irregularly formed surface, on top of each cone, generally of diameter less than 10% of the cone's height (h as shown e.g. in FIG. 1 or 3), e.g. less than 10 micrometer, especially less than 5 micrometer, preferably about 1 micrometer.

Other variants of the present photovoltaic module are shown by the cross sections given in FIGS. 5 and 6: FIG. 5 shows the structured reflector (5) as part of the back sheet (7) and arranged in close proximity to the gap between the cells (indicated in FIGS. 4-6 by “A”). FIG. 6 shows the structured reflector (5) in close proximity to the cells (3), with a further layer (6) of polymer material arranged between back sheet (7) and reflecting sheet (5); in this case, the microstructures of the present reflector (5) preferably contain or are covered by a thin polymeric material or polymer layer within the grooves of its microstructures (i.e. between cones) and potentially also on top of its apexes in order to ensure good optical contact (this thin layer is not shown in FIG. 6).

The transparent front plate (1) and the adjacent layer of the encapsulant (2) are of similar or same refractive index (“index matching”), just like subsequent components (3) and (4) in the module to avoid light reflection at the interface between both materials.

Typical materials for these components are glass like common crown or flint glass and transparent polymeric materials including thermoplastic polymers (optical quality=low haze or scattering) or polymers curable by radiation or heat. Many of these materials have refractive indices close to 1.5, for example from the range 1.45 to 1.65, commonly from the range 1.45 to 1.60.

The thickness d_{F} of the encapsulant layer (2) between the front plate (1) and the solar cell (3) typically ranges from 300 to 500 micrometers and is often around 400 micrometers. The front plate 102 typically has a thickness d₁₀₂ from the range 2.5 to 5 mm, typically about 3.2 mm.

The polymer layer or encapsulant embedding the cones as well as the PV cells is a transparent polymer material, which is often selected from polycarbonate, polyester (e.g. PET), vinyl polymers such as polyvinyl alcohol or ethylene vinyl acetate (EVA), including acrylics like polymethylmethacrylate, and the like. Examples are polycarbonate, polyacrylics such as PMMA, polyvinylbutyral, silicone polymers, polyimide, polystyrene, styrene acrylonitrile, polyamide, polyetherimide, polysulfone, cyclic olefin copolymer, and especially EVA. Optical quality of some polymers such as PE or PP can be improved by addition of clarifyers. It may consist of one bulk material (encapsulant) in contact with the structured reflecting sheet of the invention and back sheet and the PV cells, or it may comprise two or more layers of such material. The thickness of the polymer layer(s) (4), arranged adjacent to the cells and opposite to the side of main incidence of light between structured reflecting sheet (apexes) and the PV cells (3), if present, typically reaches up to 2 mm, and often ranges e.g. from 1 micrometer to about 2 mm, preferably its thickness is about 0.1 to 1 mm, especially 0.3 to 0.5 mm. The total thickness of polymer layers (4) and (6) between back sheet and the PV cells (3) typically ranges from about 0.1 to 2 mm, especially 0.1 to 0.8 mm, often depending on the materials chosen for front plate (1) and back sheet (7) (in case of glass-glass modules usually more in the upper range of thickness and typically at least 0.2 mm).

Typically, the front plate carries an antireflective element (101), which may be the textured surface of the front plate (1, 102) or it may be an antireflective coating applied to said front plate. Coatings typically are transparent or translucent porous materials with index-matching properties, e.g. comprising suitable dielectric particles such as silicon dioxide or alumina in a suitable binder, such as materials disclosed by Wicht et al. (Macromolecular Materials and Engineering 295, 628 (2010)). Coatings may be made of low refractive index materials such as MgF₂ or fluoropolymers. The antireflective element may also consist of a multi-layer interference system having alternating layers of a low refractive index material and a high refractive index material. The antireflective element may also be a film with a nanostructured surface, e.g. a film with a moth's eye structure (a structure consisting of a hexagonal pattern of bumps).

The back plate (7, 105) may be included to protect the back surface of the solar cell. It can be, for example, a non-transparent weather-resistant resin film or a multilayer stacked film which may comprise a metal foil interposed between a pair of resin films. It may also comprise an additional reflecting layer on the side directed towards the solar cells. Or it may be an optically transparent material such as glass or a transparent polymer material, especially in case of a module containing bifacial cells able to convert diffusive light incident from the back of the module.

In an especially advantageous embodiment, the layer (4) comprises or consists of a material having a refractive index higher than the remaining encapsulant, at least in the part of said layer embedding the cones. Thus, a further aspect of the invention relates to a light-reflecting film with a new structure and to the method of manufacturing it. The light-reflecting film according to the invention comprises the present reflective surface embedded into a high refractive index material distinct from the encapsulant material, unlike the reflective medium used in the art. “Embedded” means that the cones are completely covered by the high refractive index material and not just coated by a layer of constant thickness following the shape of the cones. The embedding material completely fills the spaces or grooves between the cones and has its surface receiving the incident light substantially plane.

Another aspect of the invention relates to the solar energy system comprising this new light-reflecting film. The light-reflecting films of the invention may be integrated into solar concentrators, solar modules, etc., and, more generally, into any solar system which requires an efficient light concentration.

Hereafter, the invention is detailed for the use of the light-reflecting film in a solar module. The present film generally covers the module's area free of solar cells. The present film may fit inside the gaps between the solar cells, or be set in area facing the gaps either closer towards the front side layer or closer towards the backside layer. In the module, the light-reflecting film of the invention is arranged in the area free of solar cells, or preferably as a backsheet or part of a backsheet as a layer assembly below the cells and opposite to the side of main incidence of light.

Embedding the cones of the light-reflecting films into a high refractive index layer has a variety of advantages over the other reflective films previously described.

FIG. 7 shows a cross section of a PV module as of FIG. 5, but containing an additional layer of high refractive index embedding the reflecting cones (100).

The effect of this additional layer is illustrated in FIG. 8 (cross section as in FIG. 5, front plate and cells not shown, encapsulant (103) with refractive index n₁₀₃=1.52); the light is reflected on the film (100) with an angle α decreasing as the n index (n₁₀₆) of the embedding layer increases. One advantage of this smaller angle α is that the distance D between the edge of the solar cell (104) and the area where the reflected light hits the solar cell increases. Knowing that the solar cells generally have a lower conversion efficiency in the region close to their edge, it is particularly advantageous to adapt the structure of the light-reflecting film to promote the reflection of the light into an area distant from the edge of the cell.

This effect is achieved when the film is embedded into an optically transparent material with a high refractive index (HRI). Another advantage resulting from this shallower angle α is that there is less light transmitted or, in other words, less light lost, through the antireflective structure associated with the front sheet (102): Indeed, state of the art solar modules have an antireflective structure covering the outer surface of the front side layer. This antireflective structure allows maximum use of solar light but has the effect that light is transmitted through the front side layer rather than reflected (TIR) if the angle α is too steep. To promote a total internal reflection on the front side layer, the angle α must be small enough. For this reason, embedding the microstructures of the film into a high refractive index layer is also particularly advantageous.

The structure of the light-reflecting film (100) comprising the embedding HRI layer (106) is schematically represented in the cross section shown in FIG. 9b. It is illustrated for the embodiment with the film set in the gap between two solar cells (FIG. 9a), but the structure is similar for any configuration. Cones formed in base layer (108) with apex angles β are covered with a reflective layer (107) as represented in the figures.

The layer for embedding the present microstructures consists of a light-transparent material (106) showing a refractive index higher than the refractive index of the remaining encapsulant (103), which is typically (i.e. for polymers as noted above, or index-matching glass (102)) about 1.5 (i.e., for example, from the range 1.45 to 1.55). This material (106) has a refractive index, which should be high, but generally not too high in order to avoid a total internal reflection inside the embedding material (106) or the interface between material (106) and other material crossed by the light path, such as the encapsulant (103). Thereby, the n index (n₁₀₆) for the embedding material (106) should range from 1.5 to 2.1 and, preferably, is from the range 1.6 to 1.9, or from the range 1.7 to 2.0. When the light-reflecting film is integrated into a solar module, the refractive index of the encapsulant 103 (n₁₀₃) is chosen to be lower than the refractive index (n₁₀₆) of the embedding material 106. By choosing the proportions between the refractive indices, a shallower angle of light reflection may be achieved which increases the distance D of reflection onto the solar cell and reduces light losses through the antireflective structure associated with the transparent front plate of the solar module. n₁₀₆ must be higher than n₁₀₃ but lower or equal to n₁₀₃/sin(β/2), i.e. n₁₀₃ n₁₀₆≤n₁₀₃/sin(β/2), where β is the apex angle of the cones. Most preferably, n₁₀₆ is close or equal to the upper limit n₁₀₃/sin(β/2). Table 2 lists the optimum values of n₁₀₆ for different angles β and refractive indices n₁₀₃ of the encapsulant material based on the formulae n₁₀₆=n₁₀₃/sin(β/2). For example, for β=120° and n₁₀₃=1.5, the optimum value for the refractive index n₁₀₆ is 1.73. The optimum difference between both indices is thus 0.23.

TABLE 2

| | n₁₀₃ = 1.45 | | n₁₀₃ = 1.5 | | n₁₀₃ = 1.55 | | n₁₀₃ = 1.6 | |
|---|---|---|---|---|---|---|---|---|
| β ° | n₁₀₆ | Δ n₁₀₆ n₁₀₃ | n₁₀₆ | Δ n₁₀₆ n₁₀₃ | n₁₀₆ | Δ n₁₀₆ n₁₀₃ | n₁₀₆ | Δ n₁₀₆ n₁₀₃ |
| 115 | 1.72 | 0.27 | 1.78 | 0.28 | 1.84 | 0.29 | 1.90 | 0.35 |
| 116 | 1.71 | 0.26 | 1.77 | 0.27 | 1.83 | 0.28 | 1.89 | 0.34 |
| 117 | 1.70 | 0.25 | 1.76 | 0.26 | 1.82 | 0.27 | 1.88 | 0.33 |
| 118 | 1.69 | 0.24 | 1.75 | 0.25 | 1.81 | 0.26 | 1.87 | 0.32 |
| 119 | 1.68 | 0.23 | 1.74 | 0.24 | 1.80 | 0.25 | 1.86 | 0.31 |
| 120 | 1.67 | 0.22 | 1.73 | 0.23 | 1.79 | 0.24 | 1.85 | 0.30 |
| 121 | 1.67 | 0.22 | 1.72 | 0.22 | 1.78 | 0.23 | 1.84 | 0.29 |
| 122 | 1.66 | 0.21 | 1.72 | 0.22 | 1.77 | 0.22 | 1.83 | 0.28 |
| 123 | 1.65 | 0.20 | 1.71 | 0.21 | 1.76 | 0.21 | 1.82 | 0.27 |
| 124 | 1.64 | 0.19 | 1.70 | 0.20 | 1.76 | 0.21 | 1.81 | 0.26 |
| 125 | 1.63 | 0.18 | 1.69 | 0.19 | 1.75 | 0.20 | 1.80 | 0.25 |

As apparent from Table 2, the optimum difference between n₁₀₃ and n₁₀₆ ranges from 0.15 to 0.4 and, preferably, from 0.20 to 0.35.

The optically transparent high refractive index material (106) may be an organic polymer containing sulphur, nitrogen and/or aromatics. Polymer materials of such classes are disclosed, for example, in document of Higashihara and Ueda (Macromolecules 2015, 48, 1915). The material (106) may also be an inorganic material selected from metal chalcogenides and metal nitrides, preferably of the metals Al, In, Ga, Si, Sn, Ce, Hf, Nb, Ta, Zn, Ti, Zr, and/or binary alkaline chalcogenides and binary nitrides, preferably of the above metals, especially oxides, nitrides, sulphides. Typical materials include oxides and alkoxides of titanium and/or zirconium such as titanium dioxide (anatase) and zirconium dioxide, zinc sulphide, indium oxide, tungsten oxide such as tungsten trioxide, zinc oxide, Ta₂O₅, LiTaO₃, SnN, Si₃N₄, Nb₂O₅, LiNbO₃, CeO₂, HfO₂, AlN.

The material (106) may also be a hybrid material composed of an organic polymer containing nanoparticles of an inorganic material to obtain a nanocomposite of optical quality (the term “optical quality generally requires absence of absorbents and absence of particles which would cause light scattering; this may be achieved e.g. by keeping the size of nanoparticles [diameters as determined e.g. by Tunable Resistive Pulse Sensing] below 50 nm, preferably below 20 nm, especially below 10 nm). Preferably, nanoparticles contained in such hybrid materials are made up of an inorganic material as listed above. The organic polymers may be as noted above, or other organic polymers as listed above for the encapsulant. Finally, the material (106) may be a hybrid material composed of an organic polymermodified with an inorganic high refractive index material, such as Zr(O)— or Ti(O)-modified polyvinylalcohol (hybrid polymers). Polymer materials of such classes are disclosed, for example, by Li and Yang (J. Mater. Chem., 2009, 19, 2884).

HRI layer (106) must completely fill in the textured surface and cover the cones' apexes. Preferably, the layer (106) further extends over the filled textured surface on a thickness d₁₀₆ ranging from 1 to 70 μm and, preferably, from 10 to 50 micrometers.

Compared to the depth dᵥ of the grooves between the cones, the layer (106) may further extend over the filled grooves on a thickness d₁₀₆ equal to or lower than the depth dᵥ of the grooves.

The surface of the layer (106) facing the front side generally must be smooth and essentially parallel to the surface of the front plate.

A further way to prevent internal reflection at the interface between the HRI layer (106) and the encapsulant (103) is the preparation of a gradual transition of the refractive index from the high value of n₁₀₆ to the level of n₁₀₃. This may be achieved, for example, by covering layer (106) in uncured state (i.e. wet, e.g. directly after the coating process) with a further layer of the encapsulant (103), e.g. by first coating a Ti(O)-modified polyvinylalcohol of refractive index 1.75 on the structured surface to obtain wet layer (106) in full optical contact with the cone walls and gaps between cones, followed by a second coating step bringing unmodified polyvinylalcohol (i.e. layer 103) into contact with the wet first layer (106), thus allowing formation of a gradient by diffusion.

### Manufacturing of the Light-Reflecting Film

A further aspect of the invention is the manufacturing of the light-reflecting film.

According to one embodiment of the invention, the light-reflecting film comprises a base layer 108 and, in a first step, the base layer 108 with the textured surface is prepared.

It may be prepared by various processes as a single construction or a construction made up of a substrate and a coating.

One process may be an imprinting process and, preferably, a roll-to-roll imprinting process.

In a preferred embodiment, it is prepared as a single construction by an UV imprinting process. In another embodiment, the coated substrate is prepared from a radiation curable (meth)acrylate material, and the molded (meth)acrylate material is cured by exposure to actinic radiation. For example, a curable polymeric material may be coated on a substrate film (105 or 7) and pressed against a microstructured molding tool and allowed to cure e.g. by UV irradiation to form the structured surface (108) on the substrate film. Upon removal of the molding tool, the base layer is formed comprising the substrate film and the structured coating. The structure on the imprinted surface is the inverse of structure on the tool surface, that is to say a protrusion on the tool surface will form a depression on the imprinted surface, and a depression on the tool surface will form a protrusion on the imprinted surface.

The base layer with the textured surface may alternatively be prepared by embossing. In this process, a flat film with an embossable surface is contacted to a structured tool with the application of pressure and/or heat to form an embossed surface. The entire flat film may comprise an embossable material, or the flat film may only have an embossable surface. The embossable surface may comprise a layer of a material that is different from the material of the flat film, which is to say that the flat film may have a coating of embossable material at its surface. The structure on the embossed surface is the inverse of structure on the tool surface, that is to say a protrusion on the tool surface will form a depression on the embossed surface, and a depression on the tool surface will form a protrusion on the embossed surface.

A broad range of methods are known to those skilled in this art for generating microstructured molding tools. Examples of these methods include but are not limited to photolithography, etching, discharge machining, ion milling, micromachining, and electroforming. Microstructured molding tools can also be prepared by replicating various microstructured surfaces, including irregular shapes and patterns, with a moldable material such as those selected from the group consisting of crosslinkable liquid silicone rubber, radiation curable urethanes, etc. or replicating various microstructures by electroforming to generate a negative or positive replica intermediate or final embossing tool mold. Also, microstructured molds having random and irregular shapes and patterns can be generated by chemical etching, sandblasting, shot peening or sinking discrete structured particles in a moldable material. Additionally, any of the microstructured molding tools can be altered or modified according to the procedure taught in U.S. Pat. No. 5,122,902 (Benson). The tools may be prepared from a wide range of materials including metals such as nickel, copper, steel, or metal alloys, or polymeric materials.

In a second step of the manufacturing, the base layer (108) with the textured surface is coated with the reflecting layer (107). For the reflective layer, any suitable reflective material may be used, such as, for example a reflective metallic coating as already noted above. Generally, the reflecting metallic layer is coated by vapor deposition, using well known procedures.

In an optional third step, the base layer (108) with the textured surface coated with a reflecting layer (107) may subsequently be coated with the high refractive index layer (106). Preferably the coating is applied by a solution based coating process. As already explained further above, the high refractive index layer (106) may be further coated with a layer of refractive index around 1.5 (e.g. 1.45-1.55) to create a gradient of refractive index.

Then, the resulting product may be cut into strips of appropriate size to overlap with the area free of solar cells. Preferably, the strip has the same size and shape as the area between the solar cells. When mounted in the spaces between cells (as shown in FIG. 9a), the ratio between the length W_{G} of the light-reflecting film (100) between the cells and the layer thickness (d_{F}+d₁₀₂) of the light-transparent material (103, 102) is below 8.

According to another embodiment of the invention, the light reflective film thus obtained is attached to the full backside, or most of the full backside, of the PV module, thus overlapping with the cells.

### The Solar Module

A further aspect of the invention is the method of preparing the solar modules. The method includes providing a plurality of solar cells arranged on a support substrate and connected by tabbing ribbons, providing strips of the light-reflecting films as described above, attaching the strips of films to the areas between the solar cells and optionally at the border of the solar module outside of the cell area. As aforementioned, the strips of reflective film may be not directly placed in the gap between the solar cells, but closer towards the front plate or the back plate of the solar cell. In this last case, the strips of reflective film may be laminated onto the front plate or the back plate preceding the assembly of the solar module. In an alternative method, the light reflecting sheet of the invention overlaps with the cells, or covers the back side of the module, thus providing reflection not only for light passing the area between cells, but also the “unused” light passing the cells.

In the solar module of the invention, the photovoltaic cells (3, 104) are preferably silicon cells such as monocrystalline cells or multicrystalline cells, or may be cells based on any other semiconductor material used in PV cells. The cells (3, 104) may be monofacial or bifacial cells. Of special importance within present invention are bi-facial cells, especially in combination with a reflector of the invention (5, 100) arranged below most of the cells, or ideally all of the cells, thus serving to reflect passed light back towards the cell.

Cells may be rectangular or rounded, their longest diameter is typically from the range 5 to 20 cm, the smallest diameter is typically from the range 4 to 12 cm. Thickness of the PV cells is typically 0.1 to 1 mm, espectally about 200 to 400 micrometer. PV cells are typically covered by a further layer (2) of polymeric material such as EVA or polyvinyl alcohol; polymeric material such as EVA or polyvinyl alcohol generally also fills distances A between cells.

The solar module according to the invention comprises a plurality of electrically interconnected solar cells having a front side receiving the incident light, while both front side and back side may receive reflected light. The solar cells are arranged in a pattern where at least two cells are spaced from each other by areas with no solar cells. The principle of the invention is independent of the current conventional column/row arrangement of solar cells in solar modules, and applies to any layout of cells in the solar module. The solar cells (3) typically are encapsulated within an optically transparent polymer (the encalsulant) filling the space between the front and the back sheet. Distances A between solar cells in the module often range from 1 up to 10 mm, usually from about 2 to 5 mm. Total thickness of the solar module including protective sheet, encapsulant, PV cells, wiring and back sheet typically is from the range 1 to 20 mm, especially 2 to 8 mm.

Metal structures for the use as backsheet reflector investigated are pyramids with a hexagonal base area in hexagonal periodically repeating structure as shown in FIGS. 1, 2 and 3 (apex angle 120°, height h is 25 micrometer; 50 nm metal coating on pre-structured and cured acrylic coating on polycarbonate sheet S). Mono- or bifacial passivated emitter and rear solar cells in a high efficiency module with electrical power output of 290 W, a cell gap of 4 mm and a white backsheet serve as a reference.

Realistic field irradiation conditions differ from STC in angle of incidence and spectral distribution. Hence, a yearly average light source is used to gain a more realistic prediction of the improvement due to the structured backsheets. This light source emits a mean annual daylight distribution that models the celestial hemisphere by a partition into solid-angle intervals of 5° azimuth and 5° altitude. Each of these intervals contains its own spectral distribution and intensity. For comparison, the overall intensity is normalized to 1000 W/m² in order to match the intensity of the AM1.5 irradiance.

All modules are considered facing south with a 35° tilt angle, reflectivity in each case except for the black backsheet is assumed as 100%, and zero for the black backsheet. Results are compiled in Table 3; Table 3 lists the short circuit current density (Jsc) gains that result from the backsheet changes. Results show distinct gains for mono- and for bifacial cells with structured backsheets compare to module with a white backsheet as reference.

TABLE 3
Jsc for various structured backsheets with Al and Ag reflector under
realistic irradiation. The simulation uncertainty is ±0.05 mA/cm²
(±0.2%). The gain is calculated relative to a white backsheet.

| | Monofacial | | | |
|---|---|---|---|---|
| | cell | Gain | Bifacial cell | Gain |
| Backsheet type | Jsc [mA/cm2] | [%] | Jsc [mA/cm2] | [%] |
| Black (comparison) | 37.52 | −2.2% | 36.66 | −5.2% |
| White (reference) | 38.35 | 0.0% | 38.68 | 0.0% |
| Hexagonal Al | 38.63 | 0.7% | 39.24 | 1.4% |
| pyramids | | | | |
| Hexagonal Ag | 38.85 | 1.3% | 39.49 | 2.1% |
| pyramids | | | | |

### BRIEF DESCRIPTION OF FIGURES

FIG. 1: Example for structured reflector on back sheet (cross section of PV module, reverse side up, cells not shown; a denotes the aperture angle, h denotes the height of cones, R denotes the reflecting aluminum layer, S the back sheet; mu stands for micrometer)

FIG. 2a shows a top view of the structured reflector (hexagonal setting, cones cover the whole surface which is fully metallized; contours of some cones are highlighted).

FIG. 2b shows a perspective side view of the structured reflector (hexagonal setting, cones cover the whole surface which is fully metallized).

FIG. 2c shows a schematic top view of a reflector according to the invention, which has been structured with cones of hexagonal basis (H) and triangular basis (T), which structure, or mold for such structure, is advantageously obtainable my micromachining.

FIG. 3: Single cone in hexagonal setting; aperture angle (a), height (h) and diameter (d) of the cone's base as defined above.

FIG. 4: Photovoltaic module (cross section) according to a preferred embodiment, comprising the structured reflector of the invention (5) below the cells (3) and an intermediate layer (4); the optional back sheet (7) may become attached to the reflector (5) directly as shown in FIG. 4, or separated by an additional layer, or may be omitted.

FIG. 5 shows the structured reflector (5) as part of the back sheet (7) and arranged in close proximity to the gap between the cells (indicated in FIG. 4-6 by “A”).

FIG. 6 shows the structured reflector (5) according to a preferred embodiment in close proximity to the cells (3), with a further layer (6) of polymer material arranged between back sheet (7) and reflecting sheet (5).

FIG. 7 shows a cross section of a PV module as of FIG. 5, but containing an additional layer of high refractive index embedding the reflecting cones (100).

FIG. 8 shows the path of incident light, which is reflected by the present reflecting microstructures with an angle α depending on the refractive index (n₁₀₆) of the material embedding the structures.

FIG. 9a shows an embodiment with the light reflecting microstructured film set in the gap between two solar cells (FIG. 9a).

FIG. 9b shows a cross-section of the light-reflecting film (100) comprising the additional embedding HRI layer (106) covering the cones.

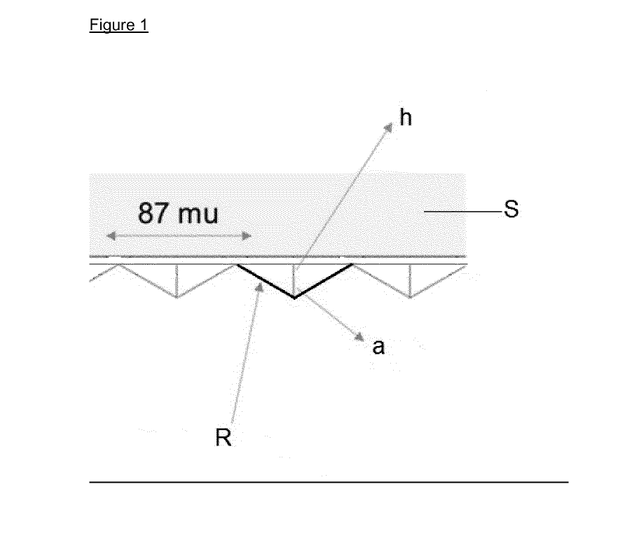

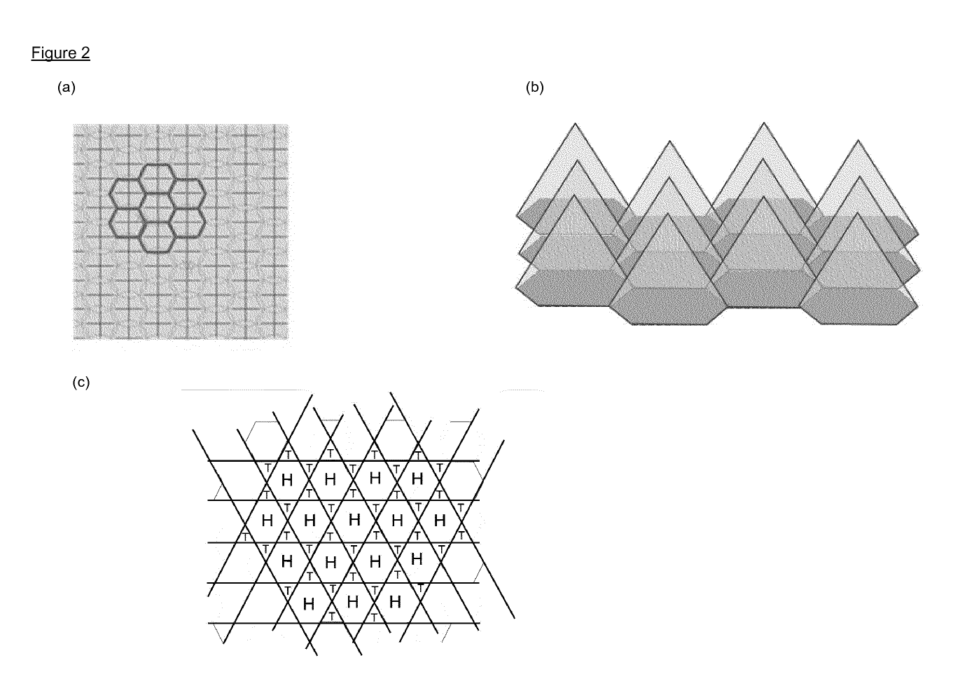

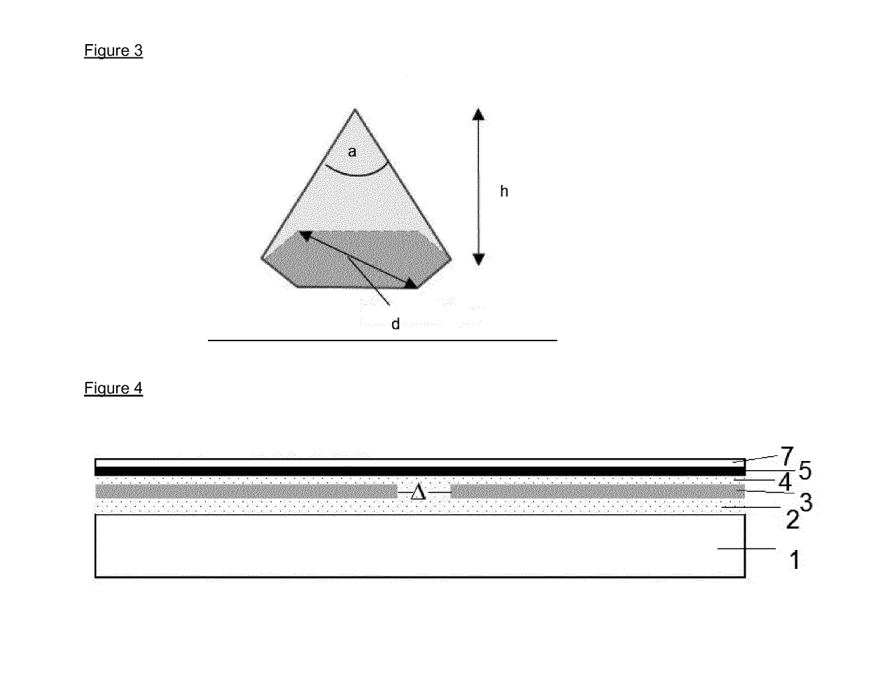

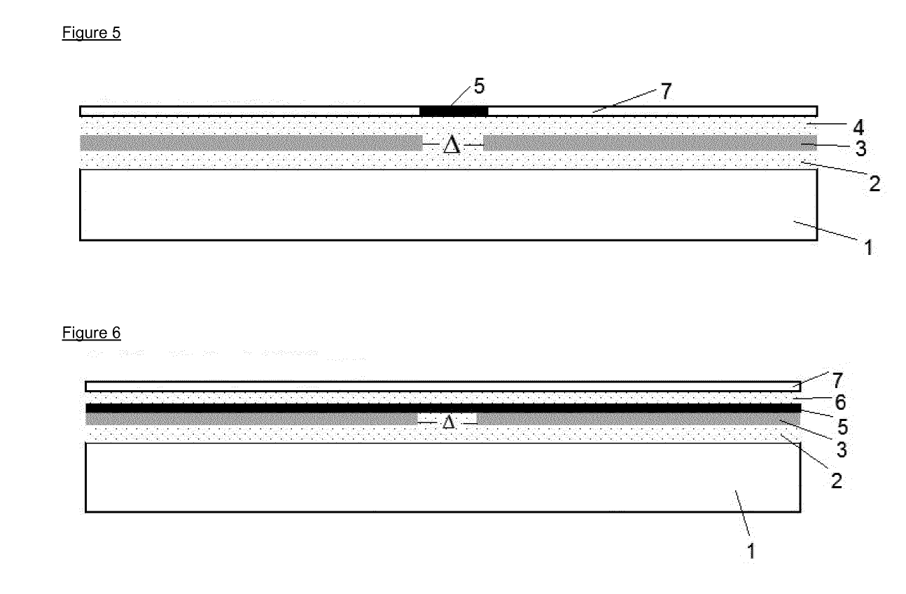

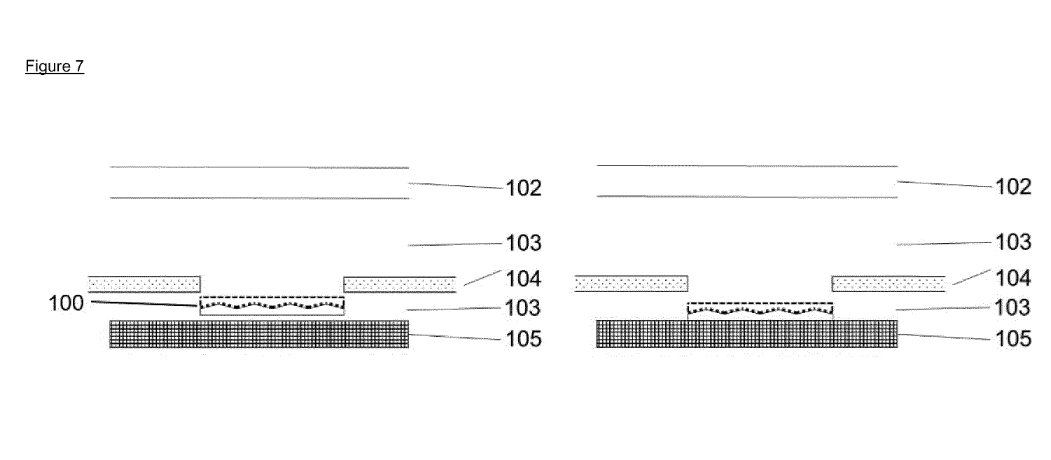

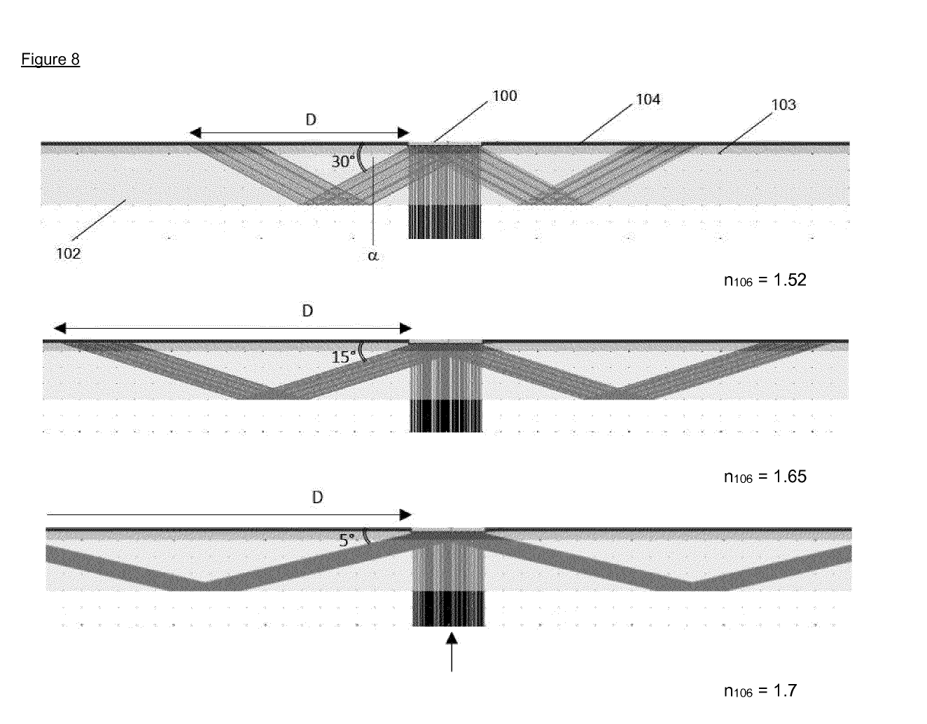

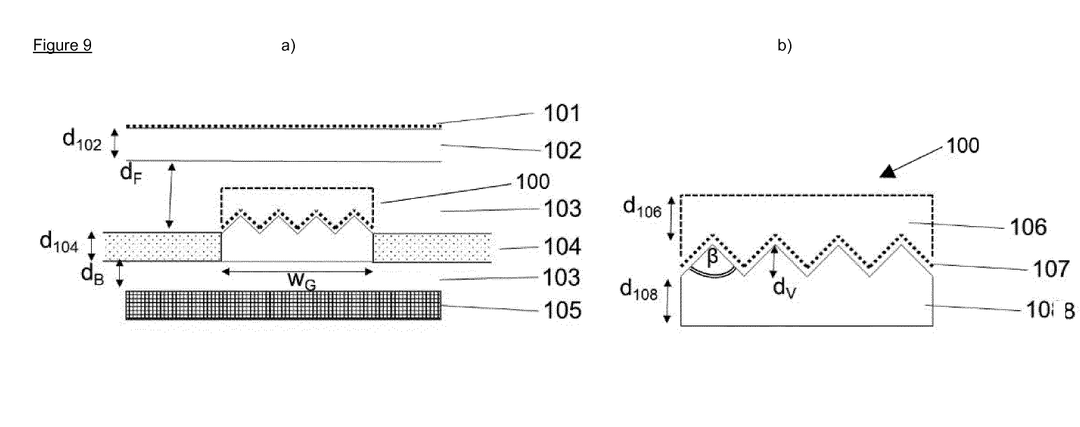

### ABBREVIATIONS

EVA poly(ethylene-vinyl acetate)
PV photovoltaic
AM1.5 air mass 1.5 irradiance conditions
HRI high refractive index (i.e. generally
Jsc short circuit current density (of PV module)
TIR total internal reflection

### NUMERALS

(1), (102) Transparent front sheet (also recalled as front plate) of PV module
(101) Antireflective element
(103) Light-transparent material/encapsulant
(2) Encapsulant (encapsulant layer above PV cells)
(3), (104) PV cells
(4) Encapsulant (layer below PV cells)
(5), (100) Structured reflector (also recalled as reflecting film) of the invention
(6) Optional encapsulant layer below structured reflector
(7), (105) Optional back plate
(106) Optional HRI layer of the light-reflecting film (embedding material)
(107) Reflective layer inside the light-reflecting film
(108) Base layer of the light-reflecting film
(109) Interface layer between the optical elements

1. A photovoltaic module comprising an upper surface and a lower surface, where an array of photovoltaic cells is arranged on one or more transparent polymer layers, characterized in that a microstructured reflector sheet is arranged below at least a fraction of the array of photovoltaic cells and below said one or more transparent polymer layers and/or is incorporated in said one or more transparent polymer layers, a surface of said microstructured reflector sheet which faces the photovoltaic module's upper surface comprising three-dimensional reflectors in the form of cones whose apexes direct towards the photovoltaic module's upper surface and whose aperture ranges from 100° to 140°.

2. The photovoltaic module according to claim 1, wherein the photovoltaic module's upper surface is an upper surface of a front sheet made of glass or transparent polymer, and the photovoltaic module's lower surface is the a lower surface of a back sheet made of glass, plastics or metal, or said materials covered by a polymer coating.

3. The photovoltaic module according to claim 1, wherein the cones on said microstructured reflector sheet extend, in a direction perpendicular to the photovoltaic module's lower surface, to a height ranging from 10 to 100 micrometers.

4. The photovoltaic module according to claim 1, wherein the surface of the microstructured reflector sheet facing the photovoltaic module's upper surface comprises a reflecting metal layer, or the microstructured reflector sheet comprises a metal film or sheet.

5. The photovoltaic module according to claim 1, wherein a transparent polymer layer of the one or more transparent polymer layers has a thickness of 1 micrometer to 2 mm and is arranged between the array of photovoltaic cells and the apexes of the microstructured reflector sheet.

6. The photovoltaic module according to claim 1, wherein lateral sides of the cones make up a full surface of the microstructured reflector sheet.

7. The photovoltaic module according to claim 2, wherein the microstructured reflector sheet is attached or integrated into the photovoltaic module's back sheet, or is incorporated in a polymer layer of the one or more polymer layers or multiple polymer layers of the one or more polymer layers between the array of photovoltaic cells and the photovoltaic module's back sheet.

8. The photovoltaic module according to claim 2, wherein the total thickness of a polymer layer of the one or more polymer layers or multiple polymer layers of the one or more polymer layers between the array of photovoltaic cells and the photovoltaic module's back sheet ranges from 100 to 800 micrometers.

9. A reflector sheet for integration into a photovoltaic module, characterized in that a surface of the reflector sheet comprises three-dimensional reflectors in the form of cones whose apexes have a height ranging from 10 to 100 micrometers, and whose aperture ranges from 100° to 140°.

10. The photovoltaic module according to claim 2 comprising the microstructured reflector sheet characterized in that the three-dimensional reflectors are embedded into a light-transparent layer covering a textured reflective surface, said light-transparent layer having a refractive index higher than the refractive index of an adjacent light-transparent polymer layer such that the difference between the refractive index of the light-transparent layer and the refractive index of the adjacent light-transparent polymer layer ranges from 0.15 to 0.4.

11. The photovoltaic module according to claim 10 comprising the microstructured reflector sheet, wherein the light-transparent layer covering the textured reflective surface has a refractive index ranging from 1.6 to 2.1.

12. The photovoltaic module according to claim 10 comprising the microstructured reflector sheet, wherein the light-transparent layer fills the textured reflective surface and has a surface opposite to the textured reflective surface substantially plane or realizing a gradient of refractive index to the adjacent light-transparent polymer layer, and wherein said light-transparent layer extends over the apexes of the surface of the microstructured reflector sheet with a thickness ranging from 1 to 70 micrometers.

13. A method for preparing a photovoltaic module, the method comprising:
incorporating a reflector sheet according to claim 9 into the photovoltaic module.

14. The method of claim 13, further comprising incorporating the reflector sheet in a space between an array of photovoltaic cells and a back sheet with the apexes of the cones facing the array of photovoltaic cells.

15. The photovoltaic module according to claim 4, wherein the metal layer or the metal film or sheet is selected from aluminum and silver.

16. The reflector sheet according to claim 9, wherein the aperture ranges from 110° to 1300°.

17. The photovoltaic module according to claim 10, wherein the difference between the refractive index of the light-transparent layer and the refractive index of the adjacent light-transparent polymer layer ranges from 0.18 to 0.35.

18. The photovoltaic module according to claim 17, wherein the difference between the refractive index of the light-transparent layer and the refractive index of the adjacent light-transparent polymer layer ranges from 0.21 to 0.35.

19. The photovoltaic module according to claim 11, wherein the light-transparent layer covering the textured reflective surface has a refractive index ranging from 1.7 to 1.9.

20. The photovoltaic module according to claim 12, wherein the light-transparent layer extends over the apexes of the surface of the microstructured reflector sheet with a thickness ranging from 10-50 micrometers.

21. The reflector sheet according to claim 9, wherein the three-dimensional reflectors are pyramidal cones whose base forms a polygon selected from the group consisting of triangle, pentangle, hexagon, heptagon and octagon.
